(19) United States
(12) Patent Application Publication
(10) Pub. No.: US 2014/0035685 A1
(43) Pub. Date: Feb. 6, 2014

(54) RESONATOR DEVICE, ELECTRONIC DEVICE, ELECTRONIC APPARATUS, AND MOBILE OBJECT

(71) Applicant: Seiko Epson Corporation, Tokyo (JP)

(72) Inventor: Seiichi Chiba, Minowa-machi (JP)

(73) Assignee: Seiko Epson Corporation, Tokyo (JP)

(21) Appl. No.: 13/950,353

(22) Filed: Jul. 25, 2013

(30) Foreign Application Priority Data
Aug. 6, 2012 (JP) 2012-173749

(51) Int. Cl. H03B 1/00

(52) U.S. Cl. CPC H03B 1/00
USPC 331/68

(57) ABSTRACT

A resonator device includes a base substrate having a fixation section to be attached to a mounting board and a free end, a resonator element having one end connected to a connection section located on the free end side of the base substrate, and a lid member adapted to airtightly seal the resonator element in a space between the lid member and the base substrate.

### BACKGROUND

1. Technical Field

The present invention relates to a resonator device, an electronic device, an electronic apparatus, and a mobile object using the resonator device.

2. Related Art

There has been proposed a quartz crystal oscillator as a resonator device having an IC chip with a rectangular shape and a resonator element mounted on a base (substrate) with a rectangular shape (see, e.g., JP-A-2002-176316 (Document 1)). In the quartz crystal oscillator described in Document 1, connection terminals are disposed on the long-side side of the IC chip, and by connecting the connection terminals along the short-side side of the base, the IC chip is mounted on the base. In addition, the resonator element is supported by both end portions on the long-side side of the base using a both end support structure, and the mounting terminals of the base are also disposed in the both end portions on the long-side side of the base.

In such a configuration as described above, deformation might be caused in the base in the case in which an external force is applied to the base (substrate) or due to the difference in thermal expansion coefficient between the mounting board and the base, and the deformation amount on the long-side side of the base is larger than that on the short-side side. In the quartz crystal oscillator described above, since the mounting terminals fixed to the mounting board and the both end support structure of the resonator element are disposed on the long-side side of the base, the quartz crystal oscillator is easily affected by the deformation of the base due to the external force or the difference in thermal expansion coefficient, and there is a problem that the variation is caused in the resonance characteristics due to the stress applied to the resonator element.

### SUMMARY

An advantage of some aspects of the invention is to solve at least a part of the problems described above, and the invention can be implemented as the following forms and application examples.

### Application Example 1

This application example is directed to a resonator device including a base substrate having a fixation section to be attached to a mounting board, a free end, and a connection section disposed between the fixation section and the free end in a plan view, a resonator element having a part attached to the connection section, and a resonating section, and a lid member adapted to airtightly seal the resonator element in a space between the lid member and the base substrate.

According to this application example, the resonator element is fixed to the base substrate on the free end side distant from the fixation section. Therefore, even in the case in which the mounting board is deformed due to an external force, heating, and so on, the stress is concentrated in the fixation section in the base substrate, and the stress hardly reaches the free end. In other words, even in the case in which the mounting board is deformed, the stress hardly reaches the resonator element connected to the base substrate in the connection section on the free end side, and it is possible to prevent the variation of the resonance characteristics of the resonator element from occurring.

### Application Example 2

This application example is directed to the resonator device according to the application example described above, wherein the fixation section includes at least two fixation portions arranged along a side of the base substrate.

According to this application example, since the fixation portions are disposed along one side of the base substrate, the distance from the fixation section to the free end can be enlarged, and therefore, a stress releasing effect can further be enhanced. Therefore, the deforming stress of the mounting board applied to the fixation section can further be inhibited from reaching the free end. In other words, the influence on the characteristics of the resonator element can further be suppressed.

### Application Example 3

This application example is directed to the resonator device according to the application example described above, wherein the fixation section includes at least two fixation portions, and a center line of the base substrate perpendicular to a direction in which the fixation portions are arranged and a center line of the resonator element along a direction in which the part and the resonating section are arranged are shifted from each other in a plan view.

According to this application example, in the case in which the mounting board is deformed, although the substrate stress (an amount of the variation of the base substrate) in the part of the center line perpendicular to the direction in which the fixation portions of the base substrate are arranged is increased, since the center line of the base substrate and the center line of the resonator element are disposed at the positions shifted from each other, it becomes possible to make the deformation of the connection section of the resonator element smaller than the deformation of the fixation section. Therefore, it becomes possible to suppress the influence of the deformation of the mounting board or the base substrate on the characteristics of the resonator element.

### Application Example 4

This application example is directed to the resonator device according to the application example described above, wherein a center line of the base substrate perpendicular to a direction in which the fixation portions are arranged and a center line of the resonator element along a direction in which the part and the resonating section are arranged are shifted from each other in a plan view.

According to this application example, in the case in which the mounting board is deformed, although the base substrate stress (an amount of the variation of the base substrate) in the part of the center line perpendicular to the direction in which the fixation portions of the base substrate are arranged is increased, since the center line of the base substrate and the center line of the resonator element are disposed at the positions shifted from each other, it becomes possible to make the deformation of the connection section of the resonator element smaller than the deformation of the fixation section. Therefore, it becomes possible to suppress the influence of the deformation of the mounting board or the base substrate on the characteristics of the resonator element.

### Application Example 5

This application example is directed to an electronic device including the resonator device according to any one of the application examples described above, and the mounting board to which the resonator device is attached.

Since the fixation section of the base substrate of the resonator device is attached to the mounting board, the cantilever fixation of the resonator device becomes possible, and thus it is difficult for the deformation of the mounting board to affect the resonator device. Further, in the resonator device used therein, since the configuration hardly affected by the deformation of the mounting board is adopted as described above, it becomes possible to provide the electronic device suppressing the variation of the characteristics due to the deformation of the mounting board.

### Application Example 6

This application example is directed to the electronic device according to the application example described above, wherein the resonator device is covered with resin.

According to this application example, the resonator device can be protected. Further, since the resin enters the gap between the resonator device and the mounting board except the fixation section, the resonator device can firmly be fixed to the mounting board, and at the same time, it is difficult for the deformation of the mounting board to affect the resonator device due to the flexibility of the resin.

### Application Example 7

This application example is directed to an electronic apparatus including the resonator device according to any one of the application examples described above.

According to this application example, since the resonator device hardly affected by the deformation of the mounting board is used, it becomes possible to provide the electronic apparatus suppressing the variation of the characteristics due to the deformation of the mounting board.

### Application Example 8

This application example is directed to a mobile object including the resonator device according to any one of the application examples described above.

According to this application example, since the resonator device hardly affected by the deformation of the mounting board is used, it becomes possible to provide the mobile object suppressing the variation of the characteristics due to the deformation of the mounting board.

### BRIEF DESCRIPTION OF THE DRAWINGS

The invention will be described with reference to the accompanying drawings, wherein like numbers reference like elements.

FIGS. 1A through 1C are schematic diagrams of a quartz crystal oscillator as the resonator device according to a first embodiment of the invention, wherein FIG. 1A is a plan view, FIG. 1B is a cross-sectional view along the Q1-Q1 line in FIG. 1A, and FIG. 1C is a bottom view of FIG. 1A.

FIGS. 2A through 2C are schematic diagrams of a quartz crystal oscillator as the resonator device according to a second embodiment of the invention, wherein FIG. 2A is a plan view, FIG. 2B is a cross-sectional view along the Q2-Q2 line in FIG. 2A, and FIG. 2C is a bottom view of FIG. 2A.

FIGS. 3A through 3C are schematic front views showing a mounting state of the quartz crystal oscillator as the resonator device.

FIG. 4 is a front cross-sectional view schematically showing an SIM card as an example of the electronic device.

FIGS. 5A and 5B are schematic diagrams showing a configuration of an IC card as an example of the electronic apparatus, wherein FIG. 5A is a plan view, and FIG. 5B is a cross-sectional view along the Q3-Q3 line in FIG. 5A.

FIG. 6 is a perspective view showing a configuration of a mobile personal computer as an example of the electronic apparatus.

FIG. 7 is a perspective view showing a configuration of a cellular phone as an example of the electronic apparatus.

FIG. 8 is a perspective view showing a configuration of a digital still camera as an example of the electronic apparatus.

FIG. 9 is a perspective view showing a configuration of a vehicle as an example of the mobile object.

### DESCRIPTION OF EXEMPLARY EMBODIMENTS

Hereinafter, some resonator devices according to the embodiments of the invention will be explained as a first embodiment and a second embodiment with reference to the accompanying drawings.

### Resonator Device According to First Embodiment

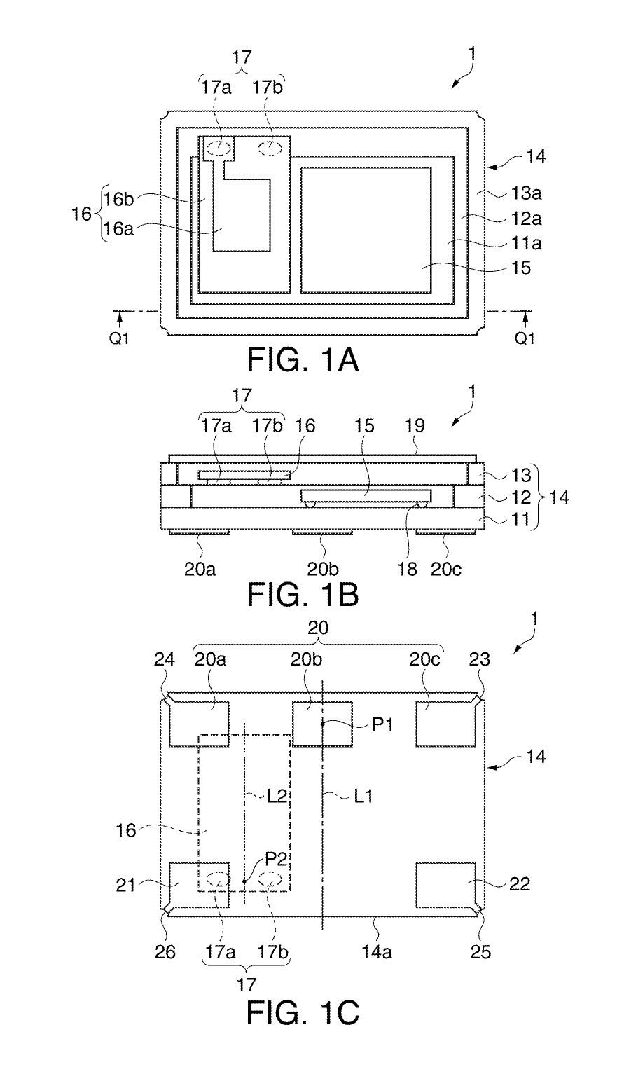

Firstly, a quartz crystal oscillator as the resonator device according to the first embodiment of the invention will be explained using FIGS. 1A through 1C. FIGS. 1A through 1C schematically show the quartz crystal oscillator as the resonator device according to the first embodiment, wherein FIG. 1A is a plan view, FIG. 1B is a cross-sectional view along the Q1-Q1 line in FIG. 1A, and FIG. 1C is a bottom view of FIG. 1A. It should be noted that FIG. 1A shows the state in which a lid member is eliminated for making the explanation easy to understand.

As shown in FIGS. 1A through 1C, the quartz crystal oscillator 1 as the resonator device has a resonator element 16 and a semiconductor device (an IC chip) 15 as an electronic component housed in a recessed section of a package 14. An opening section of the package 14 is sealed with the lid member 19 to thereby keep the inside of the package 14 airtight.

### Resonator Element

The resonator element 16 has a resonator substrate 16b formed integrally by processing a base material (a material constituting an essential part), and excitation electrodes 16a (one of principal surfaces on both sides of the resonator substrate 16b is described alone in the drawings) disposed respectively on the principal surfaces.

The base material of the present embodiment is formed of a quartz crystal substrate, and the piezoelectric material formed of the quartz crystal substrate belongs to the trigonal system, and has the crystal axes X, Y, and Z perpendicular to each other. The X axis, the Y axis, and the Z axis are called an electrical axis, a mechanical axis, and an optical axis, respectively. Further, among the quartz crystal substrates, a plate formed of a so-called rotated Y-cut quartz crystal substrate, which is carved out from the quartz crystal along a plane obtained by rotating the X-Z plane by predetermined angle θ around the X axis, is used for the resonator element.

In the present embodiment, assuming that in the orthogonal coordinate system formed of the X axis (the electrical axis), the Y axis (the mechanical axis), and the Z axis (the optical axis), the axis obtained by tilting the Z axis toward the −Y direction of the Y axis around the X axis is a Z′ axis, and the axis obtained by tilting the Y axis toward the +Z direction of the Z axis around the X axis is a Y′ axis, there is used an AT-cut quartz crystal substrate, which is composed of the planes parallel to the X axis and the Z′ axis and has a direction parallel to the Y′ axis as the thickness direction. Further, in the AT-cut quartz crystal substrate, a surface including the Z′ axis is the principal surface, and the thickness-shear vibration is excited as the principal vibration. The resonator element 16 has a rectangular shape having a direction parallel to the Y′ axis as the thickness direction, a direction parallel to the X axis as the long side, and a direction parallel to the Z′ axis as the short side.

It should be noted that the shape of the resonator element 16 is not limited to the rectangular shape, but can be a quadrangular shape other than the rectangular shape, a polygonal shape with five or more angles, a shape including an ellipse or a circle, and so on. Further, a side of a resonating section is not limited to a linear side, but can also be a side with a curvature, or in the case in which the resonating section has a polygonal outer shape, a corner portion between the side and another side connected to the side can also be provided with another side. Further, the resonator element according to the present embodiment is not limited to the AT-cut type, but can also be a resonator element of, for example, a BT-cut type exciting the thickness-shear vibration.

### Package

The package 14 has a first base substrate 11 having a plate-like shape, a second base substrate 12 having a frame-like shape and stacked on the first base substrate 11, and a third base substrate 13 having a frame-like shape and stacked on the second base substrate 12, and is provided with a recessed section for housing the semiconductor device 15 and the resonator element 16. The first base substrate 11, the second base substrate 12, and the third base substrate 13 are formed of, for example, ceramic.

The first base substrate 11 has an electronic component installation surface 11a where the semiconductor device 15 is mounted on the recessed section side, and connection electrodes (not shown) to which the semiconductor device 15 is fixed are disposed on the electronic component installation surface 11a. A plurality of electrode pads (not shown) provided to the semiconductor device 15 and the connection electrodes disposed on the electronic component installation surface 11a are respectively connected to each other with gold bumps 18 or the like. Further, some of the connection terminals are electrically connected to a plurality of external connection terminals 20a, 20b, 20c, 21, and 22 disposed on an external bottom surface of the first base substrate 11 with internal wiring not shown of the package 14.

Among the plurality of external connection terminals 20a, 20b, 20c, 21, and 22, the three external connection terminals 20a, 20b, and 20c arranged along one side of the first base substrate 11 are mounting terminals to the mounting board not shown to which the quartz crystal oscillator 1 is mounted. It should be noted that the area where the three external connection terminals 20a, 20b, and 20c are disposed corresponds to a fixation section 20 of the quartz crystal oscillator 1. Other external connection terminals 21, 22 are the terminals, which are not fixed to the mounting board. Therefore, the first base substrate 11 is fixed to the mounting board at the fixation section 20 arranged as the external connection terminals 20a, 20b, and 20c using cantilever fixation. The cantilever fixation denotes the state in which the quartz crystal oscillator 1 is fixed at one part, and at least one end of the quartz crystal oscillator 1 is set to a free end. In the quartz crystal oscillator 1, the end on the side on which the other external connection terminals 21, 22 are disposed is set to a so-called free end not fixed to the mounting board.

It should be noted that in the present embodiment, although the explanation is presented using the example in which the three external connection terminals 20a, 20b, and 20c as the fixation section 20 of the quartz crystal oscillator 1 are disposed along one side of the first base substrate 11, the arrangement of the external connection terminals as the fixation section 20 is not limited to this example. For example, the number of the external connection terminals can also be other than three. Further, the external connection terminals are not necessarily required to be arranged along the side of the first base substrate 11, but any arrangement can be adopted providing the fixation section is configured to be collected in one region.

The second base substrate 12 is formed to have a frame-like shape having an opening with a size capable of housing the semiconductor device 15 to be connected to the connection electrodes. On the second base substrate 12, there is stacked the third base substrate 13 having an opening larger than the opening of the second base substrate 12, and is fixed to the second base substrate 12. Further, the resonator element 16 is connected to a second base substrate surface 12a, which appears inside the opening of the third base substrate 13 by stacking the third base substrate 13 on the second base substrate 12. The resonator element 16 is mounted so that the connection electrodes (not shown) of the resonator element 16 correspond to element connection terminals (not shown) provided to the second base substrate surface 12a, and is fixed by bonding in a connection section 17 of the resonator element 16 with electrically-conductive adhesives 17a, 17b.

The resonator element 16 is fixed using the cantilever fixation to the second base substrate surface 12a on the free end 14a side of the first base substrate 11, which is the opposite side to the fixation section 20 of the first base substrate 11, in which the external connection terminals 20a, 20b, and 20c are disposed. The cantilever fixation denotes the state in which the resonator element 16 is fixed at one part (a fixed end), and at least one end of the resonator element 16 is set to a free end. In FIGS. 1A through 1C, assuming that the short sides of the resonator element 16 on the both sides of the excitation electrode 16a are the both ends, one of the ends is set to the fixed end while the other of the ends is set to the free end.

In other words, in the present embodiment, since the free end of the resonator element 16 is shifted closer to the fixation section 20 of the first base substrate 11 compared to the fixed end of the resonator element 16, the transmission path of the stress from the free end of the resonator element 16 to the fixation section 20 of the first base substrate 11 can be elongated.

Further, the resonator element 16 is disposed at a position in a plan view of the package 14 (the first base substrate 11) where a first center line L2 passing through the centroid P2 of the connection section 17 of the resonator element 16 and drawn in the direction perpendicular to the free end (the side) 14a of the first base substrate 11 and a second center line L1 passing through the centroid P1 of the fixation section 20 of the first base substrate 11 and drawn in the direction perpendicular to the free end (the side) 14a of the first base substrate 11 are shifted from each other, and is fixed by bonding in the element connection terminals of the second base substrate surface 12a.

By adopting such a configuration, in the case in which the mounting board is deformed, even if the substrate stress (the amount of deformation of the base substrate) in the part of the second center line L1 passing through the centroid P1 of the fixation section 20 of the package 14 (the first base substrate 11) is increased, the deformation of the connection section 17 of the resonator element 16 through which the first center line L2 passes can be made smaller than the deformation of the fixation section 20 since the first center line L2 and the second center line L1 are disposed at the positions shifted from each other. Therefore, it becomes possible to reduce the influence of the deformation of the mounting board or the first base substrate 11 on the characteristics of the resonator element 16.

Further, the lid member 19 is disposed on the upper surface 13a of the third base substrate 13 above the opening of the third base substrate 13 to thereby seal the opening of the package 14, and thus the inside of the package 14 is sealed airtightly to thereby obtain the quartz crystal oscillator 1.

The lid member 19 can be formed using, for example, metal such as “42 alloy” (an iron-nickel alloy containing nickel at 42%) or kovar (an alloy of iron, nickel, and cobalt), ceramic, or glass. For example, in the case of forming the lid member 19 with the metal, the lid member 19 is bonded to the package 14 by performing seam welding via a seal ring (not shown) formed by die-cutting the kovar alloy and so on so as to have a rectangular-ring shape. The recessed section space formed by the package 14 and the lid member 19 forms a space for the resonator element 16 to act, and is therefore preferably sealed airtightly to create a reduced-pressure space or an inert gas atmosphere.

Further, on the four corners of the package 14, there are disposed so-called castellations 23, 24, 25, and 26 each of which has a recessed shape and is provided with a wiring electrode.

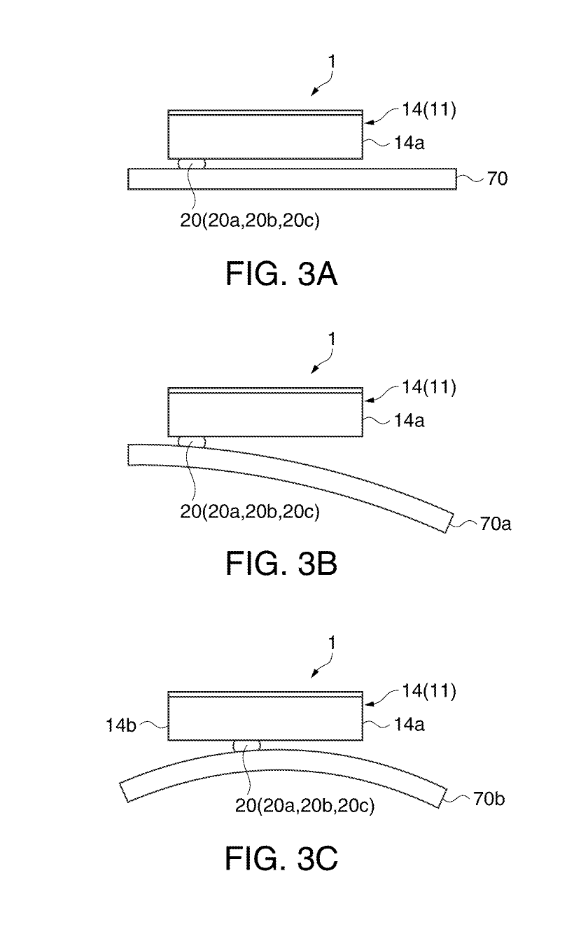

An advantage of the quartz crystal oscillator 1 according to the first embodiment described above will be explained with reference to FIGS. 1A through 1C, and 3A through 3C. FIGS. 3A through 3C are schematic front views showing the mounting state of the quartz crystal oscillator 1 as the resonator device, wherein FIG. 3A shows the state in which the mounting board is not deformed, and FIGS. 3B and 3C each show the state in which the mounting board is deformed. As shown in FIGS. 1A through 1C, and 3A, the quartz crystal oscillator 1 has the resonator element 16 connected to the package 14 (the second base substrate 12) forming the cantilever structure on the free end 14a side distant from the fixation section 20, and is fixed to the mounting board 70 using the cantilever fixation.

Therefore, in the case in which the mounting board is deformed to be the mounting board 70a shown in FIG. 3B due to an external force, heating, and so on, the stress is concentrated to the fixation section 20 in the package 14 (the first base substrate 11), and the stress hardly reaches the free end 14a side of the package 14 (the first base substrate 11). It should be noted that according to the result of a simulation of the stress generation status, it is confirmed that the stress generation in the configuration of the present embodiment is one fifth of the stress generation in the related art configuration. In other words, even in the case in which the mounting board is deformed to be the mounting board 70a, the stress hardly reaches the resonator element 16 connected to the second base substrate 12 in the connection section 17 on the free end 14a side, and it becomes possible to prevent the variation of the resonance characteristics of the resonator element 16.

It should be noted that in the case in which the fixation section 20 is located at the central portion of the package 14 (the first base substrate 11) as shown in FIG. 3C, the both ends of the package 14 (the first base substrate 11) are regarded as free ends 14a, 14b. In this configuration, even if the mounting board 70b is deformed toward the both sides centered on the fixation section 20 as shown in FIG. 3C, the portions of the free ends 14a, 14b are hardly deformed, and therefore, substantially the same advantage as described above is provided.

It should be noted that although in the explanation described above, the example in which the castellations 23, 24, 25, and 26 are disposed on the four corners of the package 14 is used, regarding the castellations, it is more preferable to eliminate the castellations 23, 24 in the end portion of the package 14 (the first base substrate 11) where the fixation section 20 is disposed. This is for obtaining an advantage that the corners existing in the end portion of the package 14 (the first base substrate 11) where the fixation section 20 is disposed function as a support for preventing the package 14 (the first base substrate 11) from being uplifted when fixing the fixation section 20 to the mounting board with molten solder or the like.

### Resonator Device According to Second Embodiment

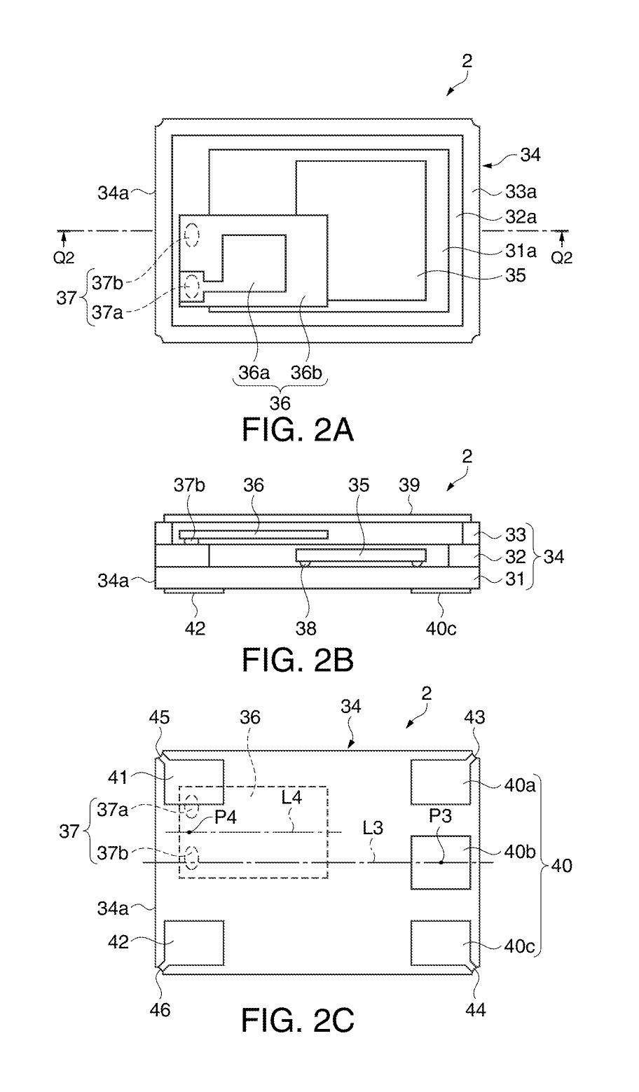

Then, a quartz crystal oscillator as the resonator device according to the second embodiment of the invention will be explained using FIGS. 2A through 2C. FIGS. 2A through 2C schematically show the quartz crystal oscillator as the resonator device according to the second embodiment, wherein FIG. 2A is a plan view, FIG. 2B is a cross-sectional view along the Q2-Q2 line in FIG. 2A, and FIG. 2C is a bottom view of FIG. 2A. It should be noted that FIG. 2A shows the state in which a lid member is eliminated for making the explanation easy to understand. Further, in the explanation of the second embodiment, the detailed explanation of the same components as in the first embodiment described above might be omitted.

As shown in FIGS. 2A through 2C, the quartz crystal oscillator 2 as the resonator device has a resonator element 36 and a semiconductor device (an IC chip) 35 as an electronic component housed in a recessed section of a package 34. An opening section of the package 34 is sealed with the lid member 39 to thereby keep the inside of the package 34 airtight.

### Resonator Element

The resonator element 36 has a resonator substrate 36b formed integrally by processing a base material (a material constituting an essential part), and excitation electrodes 36a (one of principal surfaces on both sides of the resonator substrate 36b is described alone in the drawings) disposed respectively on the principal surfaces. It should be noted that the base material is substantially the same as the base material in the first embodiment, and therefore, the explanation thereof will be omitted.

### Package

The package 34 has a first base substrate 31 having a plate-like shape, a second base substrate 32 having a frame-like shape and stacked on the first base substrate 31, and a third base substrate 33 having a frame-like shape and stacked on the second base substrate 32, and is provided with a recessed section for housing the semiconductor device 35 and the resonator element 36. The first base substrate 31, the second base substrate 32, and the third base substrate 33 are formed of, for example, ceramic.

The first base substrate 31 has an electronic component installation surface 31a where the semiconductor device 35 is mounted on the recessed section side, and connection electrodes (not shown) to which the semiconductor device 35 is fixed are disposed on the electronic component installation surface 31a. A plurality of electrode pads (not shown) provided to the semiconductor device 35 and the connection electrodes disposed on the electronic component installation surface 31a are respectively connected to each other with gold bumps 38 or the like. Further, some of the connection terminals are electrically connected to a plurality of external connection terminals 40a, 40b, 40c, 41, and 42 disposed on an external bottom surface of the first base substrate 31 with internal wiring not shown of the package 34.

Among the plurality of external connection terminals 40a, 40b, 40c, 41, and 42, the three external connection terminals 40a, 40b, and 40c arranged along one side of the first base substrate 31 are mounting terminals to the mounting board not shown to which the quartz crystal oscillator 2 is mounted. It should be noted that the area where the three external connection terminals 40a, 40b, and 40c are disposed corresponds to a fixation section 40 of the quartz crystal oscillator 2. Other external connection terminals 41, 42 are the terminals, which are not fixed to the mounting board. Therefore, the first base substrate 31 is fixed to the mounting board in the fixation section 40 arranged as the external connection terminals 40a, 40b, and 40c using the cantilever fixation, and the end on the side where the other external connection terminals 41, 42 are disposed is set to a so-called free end not fixed to the mounting board.

It should be noted that in the present embodiment, although the explanation is presented using the example in which the three external connection terminals 40a, 40b, and 40c as the fixation section 40 of the quartz crystal oscillator 2 are disposed along one side of the first base substrate 31, the arrangement of the external connection terminals as the fixation section 40 is not limited to this example. For example, the number of the external connection terminals disposed can be other than three, and further, the external connection terminals are not necessarily required to be arranged along the side of the first base substrate 31, but any arrangement of the external connection terminals can be adopted providing the fixation section is configured to be collected in one region.

The second base substrate 32 is formed to have a frame-like shape having an opening with a size capable of housing the semiconductor device 35 to be connected to the connection electrodes. On the second base substrate 32, there is stacked the third base substrate 33 having an opening larger than the opening of the second base substrate 32, and is fixed to the second base substrate 32. Further, the resonator element 36 is connected to a second base substrate surface 32a, which appears inside the opening of the third base substrate 33 by stacking the third base substrate 33 on the second base substrate 32. The resonator element 36 is mounted so that the connection electrodes (not shown) of the resonator element 36 correspond to element connection terminals (not shown) provided to the second base substrate surface 32a, and is fixed by bonding in a connection section 37 of the resonator element 36 with electrically-conductive adhesives 37a, 37b.

The resonator element 36 is fixed using the cantilever connection to the second base substrate surface 32a on the free end 34a side of the first base substrate 31, which is the opposite side to the fixation section 40 of the first base substrate 31, in which the external connection terminals 40a, 40b, and 40c are disposed.

Further, the resonator element 36 is disposed at a position in a plan view of the package 34 (the first base substrate 31) where a first center line L4 passing through the centroid P4 of the connection section 37 of the resonator element 36 and drawn in the direction perpendicular to the free end (the side) 34a of the first base substrate 31 and a second center line L3 passing through the centroid P3 of the fixation section 40 of the first base substrate 31 and drawn in the direction perpendicular to the free end (the side) 34a of the first base substrate 31 are shifted from each other, and is fixed by bonding in the element connection terminals of the second base substrate surface 32a.

By adopting such a configuration, in the case in which the mounting board is deformed, even if the substrate stress (the amount of deformation of the base substrate) in the part of the second center line L3 passing through the centroid P3 of the fixation section 40 of the package 34 (the first base substrate 31) is increased, the deformation of the connection section 37 of the resonator element 36 through which the first center line L4 passes can be made smaller than the deformation of the fixation section 40 since the first center line L4 and the second center line L3 are disposed at the positions shifted from each other. Therefore, it becomes possible to reduce the influence of the deformation of the mounting board or the first base substrate 31 on the characteristics of the resonator element 36.

Further, the lid member 39 is disposed on the upper surface 33a of the third base substrate 33 above the opening of the third base substrate 33 to thereby seal the opening of the package 34, and thus the inside of the package 34 is sealed airtightly to thereby obtain the quartz crystal oscillator 2. The configuration of the lid member 39 and the sealing method are the same as those of the first embodiment, and therefore, the explanation thereof will be omitted. The recessed section space formed by the package 34 and the lid member 39 forms a space for the resonator element 36 to act, and is therefore preferably sealed airtightly to create a reduced-pressure space or an inert gas atmosphere.

Further, on the four corners of the package 34, there are disposed so-called castellations 43, 44, 45, and 46 each of which has a recessed shape and is provided with a wiring electrode.

The quartz crystal oscillator 2 according to the second embodiment described above also has substantially the same advantage as that of the quartz crystal oscillator 1 according to the first embodiment described above. Specifically, the resonator element 36 is connected to the package 34 (the second base substrate 32) on the free end 34a side distant from the fixation section 40 using the cantilever connection, and the package 34 is fixed to the mounting board (not shown) using the cantilever fixation.

Therefore, in the case in which the mounting board is deformed due to an external force, heating, and so on, the stress is concentrated to the fixation section 40 in the package 34 (the first base substrate 31), and the stress hardly reaches the free end 34a side of the package 34 (the first base substrate 31). It should be noted that according to the result of a simulation of the stress generation status, it is confirmed that the stress generation in the configuration of the present embodiment is one fifth of the stress generation in the related art configuration. In other words, even in the case in which the mounting board is deformed, the stress hardly reaches the resonator element 36 connected to the second base substrate 32 in the connection section 37 on the free end 34a side, and it becomes possible to prevent the variation of the resonance characteristics of the resonator element 36. Further, also in the case in which the fixation section 40 is located at the central portion of the package 34 (the first base substrate 31), substantially the same advantage as that of the first embodiment described above is provided.

It should be noted that although in the explanation described above, the example in which the castellations 43, 44, 45, and 46 are disposed on the four corners of the package 34 is used, regarding the castellations, it is more preferable to eliminate the castellations 43, 44 in the end portion of the package 34 (the first base substrate 31) where the fixation section 40 is disposed. This is for obtaining an advantage that the corners existing in the end portion of the package 34 (the first base substrate 31) where the fixation section 40 is disposed function as a support for preventing the package 34 (the first base substrate 31) from being uplifted when fixing the fixation section 40 to the mounting board with molten solder or the like.

### Electronic Device

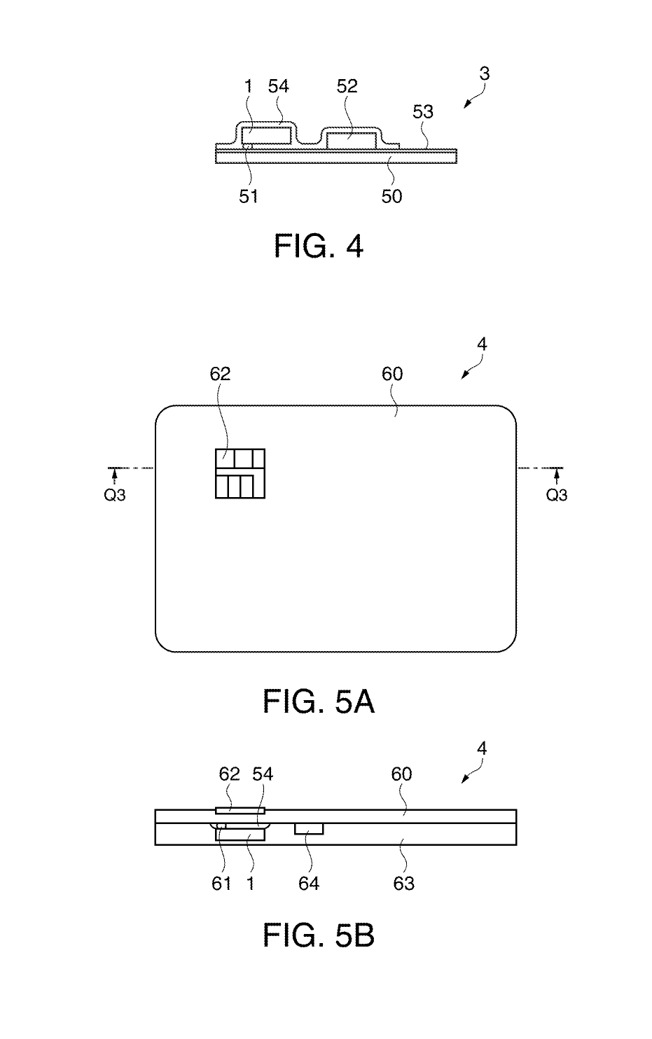

Then, an electronic device according to the embodiment using the quartz crystal oscillator 1 as the resonator device according to any one of the embodiments of the invention will be explained using FIG. 4. FIG. 4 is a front cross-sectional view schematically showing an SIM card (a Subscriber Identity Module Card) as an example of the electronic device.

As shown in FIG. 4, the SIM card 3 as an example of the electronic device has a mounting board 50 provided with conducting wiring 53, the quartz crystal oscillator 1 as the resonator device connected and fixed to the conductive wiring 53 on the mounting board 50, and an electronic component 52. The quartz crystal oscillator 1 is connected to the conductive wiring 53 on the mounting board 50 with a connection material 51 such as solder using the cantilever support. Further, except apart of the conductive wiring 53, which is a connection section to the outside, the conductive wiring 53, the quartz crystal oscillator 1, and the electronic component 52 on the mounting board 50 are overcoated with a coating material 54 made of resin such as polyvinyl chloride (PVC) or polyethylene terephthalate glycol (PET-G). The coating material 54 enters the gap between the quartz crystal oscillator 1 and the mounting board 50 except the part of the connection material 51, and firmly fixes the quartz crystal oscillator 1 and the mounting board 50 to each other. Further, the coating material 54 is softer than the connection material 51 such as solder and has flexibility.

Such an SIM card is often attached to a cellular phone in order to identify a unique ID number, and is required to be downsized and to have low profile. Therefore, since the deformation of the SIM card is easily caused by the attaching/detaching operation when attaching the SIM card, in the configuration using the resonator device (the quartz crystal oscillator 1) according to the embodiment of the invention, it becomes possible to continue the stable operation while preventing the variation of the characteristics of the resonator device (the quartz crystal oscillator 1) due to the deformation of the SIM card.

### Electronic Apparatus

Then, the electronic apparatuses to which the quartz crystal oscillator 1, 2 as the resonator device according to the embodiment of the invention or the electronic device is applied will be explained in detail with reference to FIGS. 5A, 5B, and 6 through 9. It should be noted that in the explanation, the example using the quartz crystal oscillator 1 as the resonator device will be described.

FIGS. 5A and 5B show a schematic configuration of a contact-type IC card as the electronic apparatus equipped with the quartz crystal oscillator 1 as the resonator device according to the embodiment of the invention, wherein FIG. 5A is a plan view viewed from the mounting board side, and FIG. 5B is a cross-sectional view along the Q3-Q3 line. In these drawings, the IC card 4 is provided with a mounting board 60, the quartz crystal oscillator 1 fixed to the surface of the mounting board 60 with a bonding material 61 such as solder using the cantilever fixation, and an exterior section 63 disposed on the side of the mounting board 60 to which the quartz crystal oscillator 1 and an electronic component 64 are fixed. Except the part of the bonding material 61, the coating material 54 such as resin described above is disposed between the mounting board 60 and the quartz crystal oscillator 1. The coating material 54 can also be disposed so as to cover the whole of the quartz crystal oscillator 1. Further, on the reverse side of the surface of the mounting board 60 to which the quartz crystal oscillator 1 and the electronic component 64 are fixed, there is disposed an electrode 62, which is electrically connected to the electronic component 64 with conductive wiring not shown.

In the IC card 4, a variety of information is held by a semiconductor device (an IC chip) not shown incorporated in the quartz crystal oscillator 1, and reading and writing of the information are performed using a card reader.

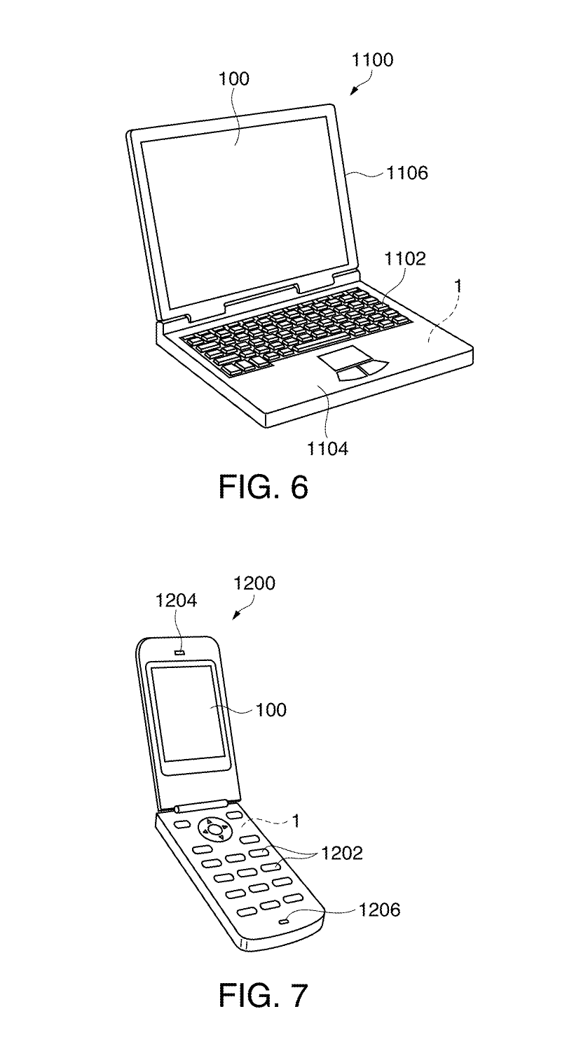

FIG. 6 is a perspective view showing a schematic configuration of a mobile type (or a laptop type) personal computer as the electronic apparatus equipped with the quartz crystal oscillator 1 according to the embodiment of the invention. In the drawing, the personal computer 1100 includes a main body section 1104 provided with a keyboard 1102, and a display unit 1106 provided with a display section 100, and the display unit 1106 is pivotally supported with respect to the main body section 1104 via a hinge structure. Such a personal computer 1100 incorporates the quartz crystal oscillator 1.

FIG. 7 is a perspective view showing a schematic configuration of a cellular phone (including PHS) as the electronic apparatus equipped with the quartz crystal oscillator 1 according to the embodiment of the invention. In this drawing, the cellular phone 1200 is provided with a plurality of operation buttons 1202, an ear piece 1204, and a mouthpiece 1206, and the display section 100 is disposed between the operation buttons 1202 and the ear piece 1204. Such a cellular phone 1200 incorporates the quartz crystal oscillator 1.

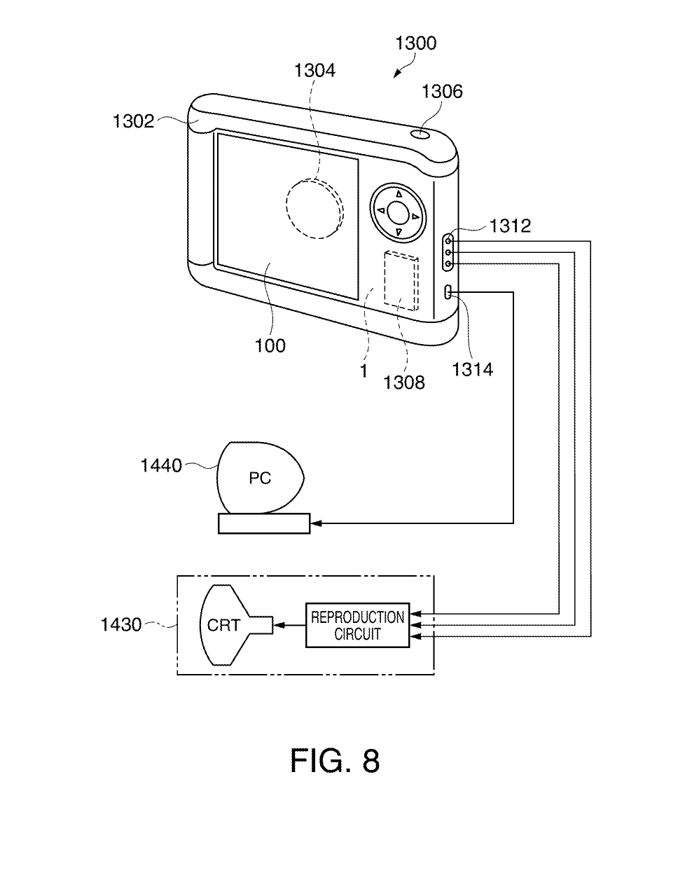

FIG. 8 is a perspective view showing a schematic configuration of a digital still camera as the electronic apparatus equipped with the quartz crystal oscillator 1 according to the embodiment of the invention. It should be noted that the connection with external equipment is also shown briefly in this drawing. Here, the conventional cameras expose a silver salt film to an optical image of an object, while the digital still camera 1300 performs photoelectric conversion on an optical image of an object by an imaging element such as a CCD (a charge coupled device) to generate an imaging signal (an image signal).

A case (a body) 1302 of the digital still camera 1300 is provided with the display section 100 disposed on the back surface thereof to have a configuration of performing display in accordance with the imaging signal from the CCD, wherein the display section 100 functions as a viewfinder for displaying the object as an electronic image. Further, the front surface (the back side in the drawing) of the case 1302 is provided with a light receiving unit 1304 including an optical lens (an imaging optical system), the CCD, and so on.

When the photographer checks an object image displayed on the display section 100, and then holds down a shutter button 1306, the imaging signal from the CCD at that moment is transferred to and stored in the memory device 1308. Further, the digital still camera 1300 is provided with video signal output terminals 1312 and an input-output terminal 1314 for data communication disposed on a side surface of the case 1302. Further, as shown in the drawing, a television monitor 1430 and a personal computer 1440 are respectively connected to the video signal output terminals 1312 and the input-output terminal 1314 for data communication according to needs. Further, there is adopted the configuration in which the imaging signal stored in the memory device 1308 is output to the television monitor 1430 and the personal computer 1440 in accordance with a predetermined operation. Such a digital still camera 1300 incorporates the quartz crystal oscillator 1.

It should be noted that, the quartz crystal oscillator 1 according to the embodiment of the invention can also be applied to an electronic apparatus such as an inkjet ejection device (e.g., an inkjet printer), a laptop personal computer, a television set, a video camera, a video cassette recorder, a car navigation system, a pager, a personal digital assistance (including one with a communication function), an electronic dictionary, an electric calculator, a computerized game machine, a word processor, a workstation, a video phone, a security video monitor, a pair of electronic binoculars, a POS terminal, a medical device (e.g., an electronic thermometer, an electronic manometer, an electronic blood sugar meter, an electrocardiogram measurement instrument, an ultrasonograph, and an electronic endoscope), a fish detector, various types of measurement instruments, various types of gauges (e.g., gauges for a vehicle, an aircraft, or a ship), and a flight simulator besides the personal computer (the mobile personal computer) shown in FIG. 6, the cellular phone shown in FIG. 7, and the digital still camera shown in FIG. 8.

### Mobile Object

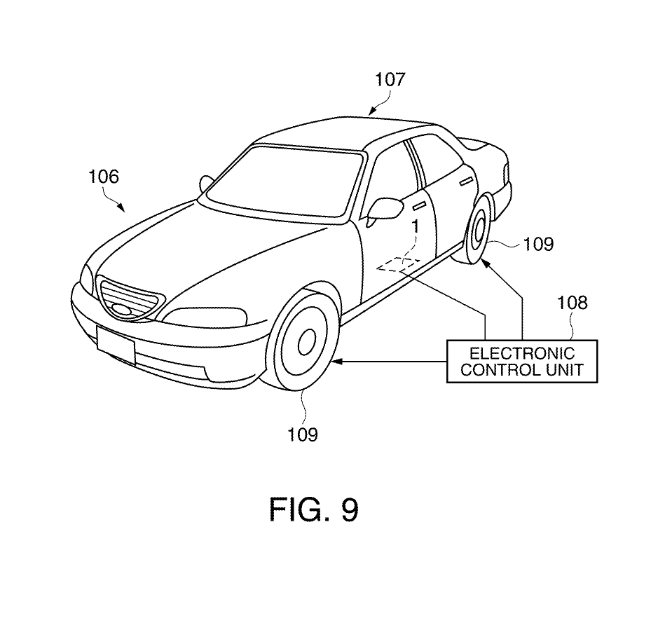

FIG. 9 is a perspective view schematically showing a vehicle as an example of the mobile object. The vehicle 106 is equipped with the quartz crystal oscillator 1 as an example of the resonator device according to the invention. For example, as shown in the drawing, in the vehicle 106 as the mobile object, an electronic control unit 108 incorporating the quartz crystal oscillator 1 and for controlling tires 109 and so on is installed in a vehicle body 107. Further, besides the above, the quartz crystal oscillator 1 can widely be applied to an electronic control unit (ECU) such as a keyless entry system, an immobilizer, a car navigation system, a car air-conditioner, an anti-lock braking system (ABS), an air-bag system, a tire pressure monitoring system (TPMS), an engine controller, a battery monitor for a hybrid car or an electric car, or a vehicle posture control system.

The entire disclosure of Japanese Patent Application No. 2012-173749, filed Aug. 6, 2012 is expressly incorporated by reference herein.

What is claimed is:

1. A resonator device comprising:
a base substrate having a fixation section to be attached to a mounting board, a free end, and a connection section disposed between the fixation section and the free end in a plan view;
a resonator element having a part attached to the connection section, and a resonating section; and
a lid member adapted to airtightly seal the resonator element in a space between the lid member and the base substrate.

2. The resonator device according to claim 1, wherein
the fixation section includes at least two fixation portions arranged along a side of the base substrate.

3. The resonator device according to claim 1, wherein
the fixation section includes at least two fixation portions, and
a center line of the base substrate perpendicular to a direction in which the fixation portions are arranged and a center line of the resonator element along a direction in which the part and the resonating section are arranged are shifted from each other in a plan view.

4. The resonator device according to claim 2, wherein
a center line of the base substrate perpendicular to a direction in which the fixation portions are arranged and a center line of the resonator element along a direction in which the part and the resonating section are arranged are shifted from each other in a plan view.

5. An electronic device comprising:
the resonator device according to claim 1; and
the mounting board to which the resonator device is attached.

6. An electronic device comprising:
the resonator device according to claim 2; and
the mounting board to which the resonator device is attached.

7. An electronic device comprising:
the resonator device according to claim 3; and
the mounting board to which the resonator device is attached.

8. An electronic device comprising:
the resonator device according to claim 4; and
the mounting board to which the resonator device is attached.

9. The electronic device according to claim 5, wherein
the resonator device is covered with resin.

10. The electronic device according to claim 6, wherein
the resonator device is covered with resin.

11. The electronic device according to claim 7, wherein
the resonator device is covered with resin.

12. The electronic device according to claim 8, wherein
the resonator device is covered with resin.

13. An electronic apparatus comprising:
the resonator device according to claim 1.

14. An electronic apparatus comprising:
the resonator device according to claim 2.

15. An electronic apparatus comprising:
the resonator device according to claim 3.

16. An electronic apparatus comprising:
the resonator device according to claim 4.

17. A mobile object comprising:
the resonator device according to claim 1.

18. A mobile object comprising:
the resonator device according to claim 2.

19. A mobile object comprising:
the resonator device according to claim 3.

20. A mobile object comprising:
the resonator device according to claim 4.
